(19) United States
(12) Patent Application Publication
(10) Pub. No.: US 2009/0117344 A1
(43) Pub. Date: May 7, 2009

(54) METHOD OF CORRECTING MASK PATTERN, PHOTO MASK, METHOD OF MANUFACTURING SEMICONDUCTOR DEVICE, AND SEMICONDUCTOR DEVICE

(76) Inventor: Koji Tamura, Fukuyama-shi (JP)

Correspondence Address: NIXON & VANDERHYE, PC, 901 NORTH GLEBE ROAD, 11TH FLOOR, ARLINGTON, VA, 22203, US

(21) Appl. No.: 12/167,497

(22) Filed: Jul. 3, 2008

(30) Foreign Application Priority Data
Nov. 7, 2007 (JP) 2007-290134

(51) Int. Cl. B32B 5/00; G03F 1/00; G03F 7/20

(52) U.S. Cl. 428/195.1; 430/5; 430/319

(57) ABSTRACT

A method of correcting a mask pattern, the method correcting the mask pattern of a mask such that a wiring pattern having desired dimensions is formed based on a micro-fabrication process using the mask, corrects the mask pattern so that, before carrying out the micro-fabrication process, an etching proximity effect is dealt with by use of the correction model in which a pattern size and a inter-patter space size are set as parameters. This makes it possible to correct the mask pattern with high accuracy so that the wiring pattern having the desired dimensions is formed on the substrate, thereby dealing with the etching proximity effect.

This Nonprovisional application claims priority under 35 U.S.C. § 119(a) on Patent Application No. 290134/2007 filed in Japan on Nov. 7, 2007, the entire contents of which are hereby incorporated by reference.

### FIELD OF THE INVENTION

The present invention relates to a method of correcting a mask pattern in manufacture of a semiconductor device, a photo mask manufactured by this method, a method of manufacturing a semiconductor device, a semiconductor device manufactured by this method, and more particularly to art directed to an improvement in deterioration of accuracy of a fine pattern formation caused by a process proximity effect.

### BACKGROUND OF THE INVENTION

As an improvement in speed and high integration of semiconductor devices have been advanced today, fine transistors and fine wiring patterns have been required. In this regard, downsizing of gate dimensions is particularly known to be effective in an improvement in speed and high integration of the transistors. Actually, very fine gate line width of not more than 100 nm has been used today.

A variance in gate line widths directly affects characteristics and qualities of transistors. Thus, in order to reduce the variance in gate line widths, an Optical Proximity Correction (OPC) technique has been introduced into a field of transistor manufacture, the technique for correcting a variance in patterns (hereinafter referred to as inter-pattern variance) caused by shifting of transferred mask patterns (hereinafter referred to as pattern shift) during a lithography process in a manufacturing process of the transistors.

Besides, it is known that, during an etching process and/or a manufacturing process of a mask in a manufacturing process of a transistor, an inter-pattern variance in pattern shifts caused by proximity effect ultimately leads to a variance in gate line widths of the wiring patterns formed on a wafer (substrate). In this regard, a Process Proximity Correction (PPC) technique for correcting an inter-pattern variance in pattern shifts caused by the proximity effect has been discussed recently.

As described above, in manufacturing of transistors, i.e., ultimately in manufacturing of a semiconductor device, it is necessary to carry out a correction of mask patterns, by taking into consideration the inter-pattern variance caused by the proximity effect. This allows a gate line width to be realized as designed. Various proposals have been made for methods and systems of correcting mask patterns in manufacturing of semiconductor devices. For example, the ProGen Template Programming Guide (Synopsys, Inc, September 2006) (publicly known document 1) discloses a method of preparing a correction model dealing with the etching proximity effect.

FIG. 8 is a flow chart showing a preparing flow of a correction model dealing with an etching proximity effect, which correction model is disclosed in the publicly known document 1 (hereinafter referred to as an etching proximity effect correction model).

To begin with, an etch shift, indicative of a pattern shift in an etching process, is measured based on (i) a pattern width that has not been subjected to the etching process and (ii) a pattern width that has been subjected to the etching process, by use of a mask pattern (hereinafter referred to as an etching proximity effect evaluation pattern) for evaluating the proximity effect in the etching process (step S51).

Subsequently, with the use of a correction model, a fitting is carried out, based on a least-squares method, with respect to the etch shift measured by use of the etching proximity effect evaluation pattern (step S52). In the correction model, (i) a density of a pattern (hereinafter referred to as pattern density) and (ii) a function of a space between patterns (hereinafter referred to as inter-pattern space) are set as parameters. In this fitting, a coefficient of the pattern density and a coefficient of the function of the inter-pattern space are calculated by using a function 1/R in the correction model, R indicating the function of the inter-pattern space.

Thus, the etching proximity effect correction model is prepared (step S53). FIGS. 9(a) and 9(b) show relations between the etching proximity effect correction model and the actual measurements of the etch shift caused by the actual etching proximity effect.

FIG. 9(a) shows (i) how an etch shift (see square-shaped points in FIG. 9(a)) varies depending on an inter-pattern space in the etching proximity effect correction model and (ii) how the actual measurement of an etch shift (circular-shaped points in FIG. 9(a)) varies depending on an inter-pattern space. In FIG. 9(a), the horizontal axis shows the width (nm) of the inter-pattern space and the vertical axis shows the etch shift (nm).

FIG. 9(b) shows a result obtained by fitting the values of the etch shift in the etching proximity effect correction model as shown in FIG. 9(a) to the actual measurements of the etch shift as shown in FIG. 9(a). The horizontal axis shows the width of the inter-pattern space (nm) and the vertical axis shows the residual error (nm) generated in the fitting (model fitting residual error).

Thus, the art disclosed in the publicly known document 1 can prepare an etching proximity effect correction model having the fitting result as shown in FIG. 9(b). It is possible to realize a wiring pattern having a gate line width close to designed dimensions, by (i) preparing a mask having the mask pattern corrected with the use of the etching proximity effect correction model and then (ii) carrying out the etching with the use of the mask thus prepared.

However, according to the etching proximity effect correction model described above, there remains a model fitting residual error of more than 5 nm, as shown in FIG. 9(b), in (i) a narrower space region (indicated by X in FIG. 9(b)) where the width of the inter-pattern space is less than 0.2 μm (ii) an intermediate space region (indicated by Y in FIG. 9(b)) where the width of the inter-pattern space falls in a range from 0.2 μm to 2 μm and (iii) a wider space region (indicated by Z in FIG. 9(b)) where the width of the inter-pattern space is more than 5 μm. This is because accuracy of the etching proximity effect correction model is not high in space regions x, y, and z shown in FIG. 9(a).

Therefore, according to the art disclosed in the publicly known document 1, it is not possible to prepare a highly accurate etching proximity effect correction model. This causes a problem that it is not possible to form, with accurate dimensions as designed, an ultimate wiring pattern on the substrate of a semiconductor device.

### SUMMARY OF THE INVENTION

The present invention is made in the view of the problem, and an object of the present invention is to provide: a method of correcting a mask pattern, in which method a mask pattern can be corrected with high accuracy in view of an etching proximity effect so that a wiring pattern having desired dimensions is formed on a substrate; a photo mask formed by this method; a method of manufacturing a semiconductor device; and a semiconductor device manufactured by this method.

In order to attain the object, a method for correcting a mask pattern in accordance with the present invention is a method correcting the mask pattern of the mask such that a wiring pattern having desired dimensions is formed based on a micro-fabrication process using the mask, wherein before carrying out the micro-fabrication process, the mask pattern is corrected so that an etching proximity effect is dealt with, by use of a correction model in which a pattern size and an inter-pattern space size are set as parameters.

With this arrangement, before carrying out the micro-fabrication process, the mask pattern of the mask used in the micro-fabrication process is corrected so that the etching proximity effect is dealt with, by use of the correction model in which the pattern size and the inter-pattern space size are set as the parameters. In addition, since the pattern size and the inter-pattern space size are set as the parameters in the correction model, the correction model is prepared accurately. Thus, the mask pattern can be corrected with high accuracy so that a wiring pattern having desired dimensions is formed on the substrate, thereby dealing with the etching proximity effect.

Also, a photo mask in accordance with the present invention includes a mask pattern that has been subjected to a correction so that the etching proximity effect is dealt with, by use of the correction model in which the pattern size and the inter-pattern space size are set as the parameters.

With this arrangement, since the pattern size and the inter-pattern space size are set as the parameters in the correction model, the correction model is prepared accurately. Thus, it is possible to realize the mask having the mask pattern that is corrected with high accuracy so that a wiring pattern having desired dimensions is formed on the substrate, thereby dealing with the etching proximity effect.

Besides, a method of manufacturing a semiconductor device in accordance with the present invention, a method in which the wiring pattern is formed on the substrate based on the micro-fabrication process using the mask, includes the steps of: correcting the mask pattern of the mask so that the etching proximity effect is dealt with, by use of the correction model in which the pattern size and the inter-pattern space size are set as the parameters; and forming the wiring pattern on the substrate in the micro-fabrication process, by use of the mask having the mask pattern that has been subjected to the correction

With this arrangement, the mask is formed, the mask having the mask pattern that has been subjected to the correction so that the etching proximity effect is dealt with, by use of the correction model in which the pattern size and the inter-pattern space size are set as the parameters. Then, the wiring pattern is formed on the substrate in the micro-fabrication process, by use of the mask. In addition, since the pattern size and the inter-pattern space size are set as the parameters in the correction model, the correction model is prepared accurately. Thus, it is possible to form the wiring pattern having desired dimensions on the substrate with high accuracy.

In addition, a semiconductor device in accordance with the present invention includes the wiring pattern formed on the substrate based on the micro-fabrication process using the mask having the mask pattern that has been subjected to the correction so that the etching proximity effect is dealt with by use of the correction model in which the pattern size and the inter-pattern space size are set as the parameters.

With this arrangement, since the pattern size and the inter-pattern space size are set as the parameters in the correction model, the correction model is prepared accurately. By this, the mask pattern of the mask is corrected with high accuracy so that the etching proximity effect is dealt with. Thus, it is possible to realize a semiconductor device, on the substrate of which the wiring pattern having the desired dimensions is formed with high accuracy.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a flow chart showing a preparing process of a correction model used in a method for correcting a mask pattern in accordance with the present invention.

FIG. 2(a) is a cross sectional view showing a manufacturing process of a semiconductor device.

FIG. 2(b) is a cross sectional view showing a manufacturing process of a semiconductor device.

FIG. 3 is a top view of FIG. 2(b), viewed from a direction in which a gate wiring pattern is formed.

FIG. 4(a) is a graph showing a relation between a correction model and an actual measurement.

FIG. 4(b) is a graph showing a residual error generated when an etch shift calculated from a correction model is fit to the actual measurement.

FIG. 5(a) is an explanatory diagram showing a pattern size of the gate wiring pattern in a one-dimension.

FIG. 5(b) is an explanatory diagram showing an inter-pattern space size of the gate wiring pattern in a one-dimension.

FIG. 6(a) is an explanatory diagram showing a pattern size of the gate wiring pattern in a two-dimension.

FIG. 6(b) is an explanatory diagram showing an inter-pattern space size of the gate wiring pattern in a two-dimension.

FIG. 7 is a flow chart showing a process for manufacturing the semiconductor device in accordance with the present invention.

FIG. 8 is a flow chart showing a preparing process for a conventional correction model.

FIG. 9(a) is a graph showing a relation between a conventional correction model and an actual measurement.

FIG. 9(b) is a graph showing a residual error generated when an etch shift calculated from a conventional correction model is fit to the actual measurement.

### DESCRIPTION OF THE EMBODIMENTS

One embodiment of the present invention is described below with reference to drawings.

A method for correcting a mask pattern in accordance with the present invention is a method capable of correcting a mask pattern to deal with the etching proximity effect, by use of a highly accurate etching proximity effect correction model, so that the wiring pattern having desired dimensions is ultimately formed on a substrate. The following description first deals with a preparing process (method) of an etching proximity effect correction model used in a method for correcting a mask pattern in accordance with the present embodiment, and then deals with a method of manufacturing a semiconductor device, in which method a mask corrected by the method of correcting the mask pattern is used. The following description deals with a case, as an example, in which a method for correcting the mask pattern in accordance with the present embodiment is applied to a mask pattern of a gate.

[A Method of Preparing Etching Proximity Effect Correction Model]

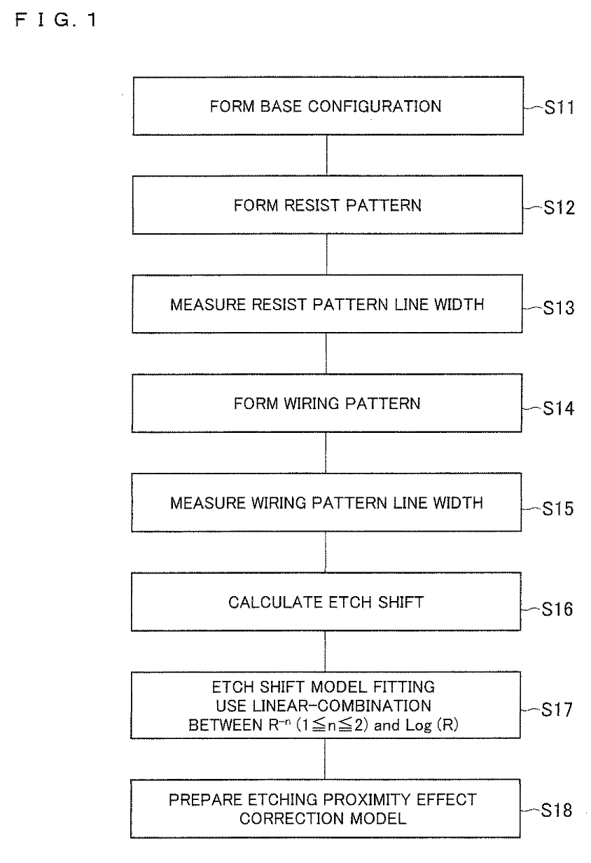

With reference to FIGS. 1 through 6(b), the following description deals with a method of preparing an etching proximity effect correction model.

FIG. 1 is a flow chart showing a preparing flow of an etching proximity effect correction model used in a method for correcting a mask pattern in accordance with the present embodiment.

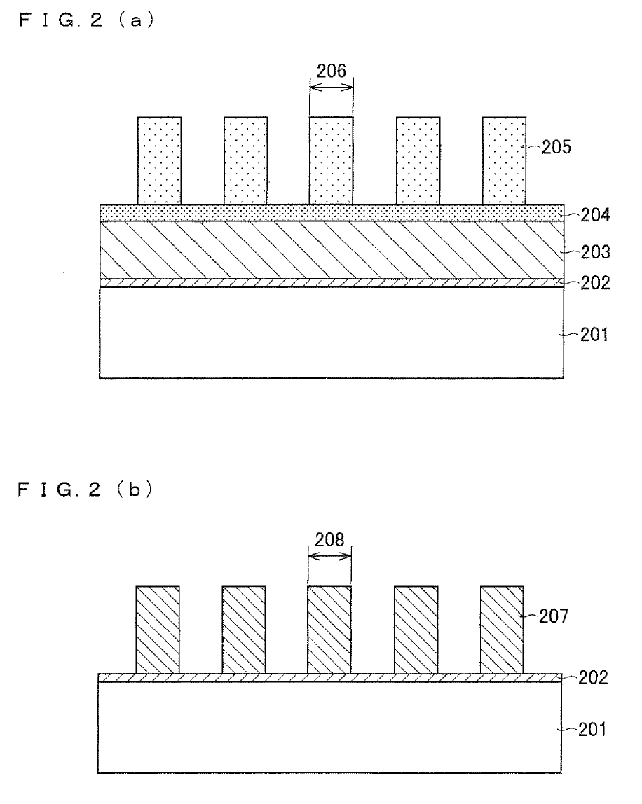

First, in order that an etching proximity effect correction model is prepared for forming a gate, a base configuration serving as a base is formed (step S11). Specifically, as shown in FIG. 2(a), a gate insulation film 202, a polycrystalline silicon film 203, and an organic antireflective film 204 are formed in this order on a semiconductor substrate 201 so as to form a base configuration.

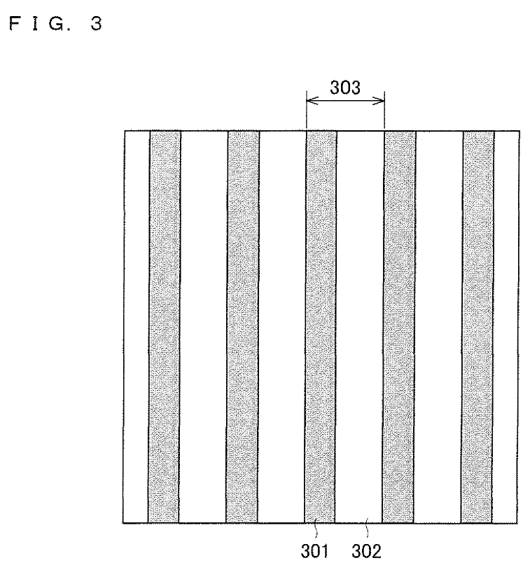

Subsequently, on the organic antireflective film 204, a lithography process is carried out with the use of a photo mask having an etching proximity effect evaluation pattern so as to form a resist pattern 205 on the organic antireflective film 204, as shown in FIG. 2(a) (step S12). At this stage, a repeat pattern is used as for the etching proximity effect evaluation pattern. In the repeat pattern, as shown in FIG. 3, a pattern 301 and a space (an inter-pattern space 302) between adjacent patterns 301 are alternately provided at a predetermined pattern pitch 303.

The etching proximity effect in the etching affects a pattern shift substantially within a 100 μm radius from an etching point. As such, it is preferable to use an etching proximity effect evaluation pattern in which a repeat pattern is provided so as to include a plurality of combinations of a pattern 301 having a width falling in a range from 0.1 μm to 0.5 μm and an inter-pattern space 302 having a width falling in a range from 0.1 μm to 5 μm. It is more preferable to use an etching proximity effect evaluation pattern in which a repeat pattern is provided so as to include a plurality of combinations of a pattern 301 having a width falling in a range from 00.5 μm to 1 μm and a pattern space 302 having a width falling in a range from 0.05 μm to 10 μm.

Then, a resist pattern line width 206 of a lower part (the part making contact with the organic antireflective film 204) of the resist pattern 205 formed with the use of the etching proximity effect evaluation pattern is measured with a CD-SEM (SEM: scanning electron microscope) (step S13).

Then, a wiring pattern of the gate is formed (step S14). Specifically, in the state shown in FIG. 2(a), while the resist pattern 205 is used as a mask, a dry etching is carried out with respect to the organic antireflective film 204 by use of an etching gas such as O₂ or Cl₂ so that the polycrystalline silicon film 203 is exposed. Successively after this, the dry etching is carried out with respect to the polycrystalline silicon film 203 by use of an etching gas such as C_{X}F_{Y}, Cl₂, HBr, or O₂. Subsequently, the resist pattern 205 is removed based on the plasma ashing using an ashing gas such as oxygen, and then a post-etching cleaning process is carried out with the use of hydrofluoric acid, sulfuric acid or other acid, thereby resulting in that a gate wiring pattern 207 is formed, as shown in FIG. 2(b).

Then, a gate wiring pattern line width 208 of a lower part (the part making contact with the gate insulation film 202) of the gate wiring pattern 207 formed with the use of the etching proximity effect evaluation pattern is measured with the use of the CD-SEM (step S15).

Then, an etch shift indicative of a pattern shift in the etching process carried out at the step S14 is calculated (step S16). Specifically, an etch shift can be calculated easily with the use of the following equation (1).

Etch shift=gate wiring pattern line width 208−resist pattern line width 206; equation (1).

Then, a fitting is carried out based on the least-squares method with respect to the etch shift calculated at the step S16, by use of a correction model in which a pattern size and an inter-pattern space size are used as parameters (step S17). For a pattern size, a width value is extracted as a value indicating a size of the pattern 301. In addition, for an inter-pattern space size, a width value is extracted as a value indicating a size of the inter-pattern space 302.

In the fitting, (i) a correction model is prepared so as to include at least an equation in which a function R⁻ⁿ (n: a positive real number) and a logarithmic function Log(R) are linearly combined, where the parameter of the inter-pattern space size is R, then (ii) a coefficient of the pattern size and a coefficient of the inter-pattern space size are respectively calculated based on such a correction model.

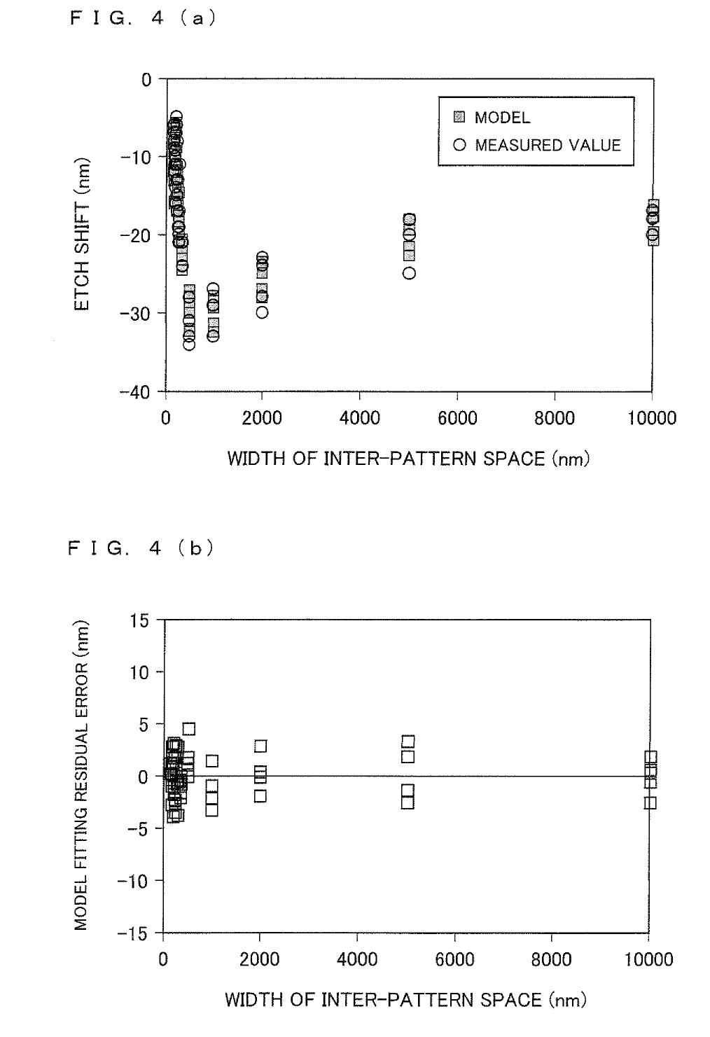

By this, the correction model reflecting the etching proximity effect, that is to say, the etching proximity effect correction model, is prepared (step S18). FIGS. 4(a) and 4(b) show relations between the etching proximity effect correction model and actual measurements obtained when the etch shift caused by the actual etching proximity effect is measured.

FIG. 4(a) shows (i) how an etch shift (see square-shaped points in FIG. 4(a)) varies depending on an inter-pattern space 302 in the etching proximity effect correction model and (ii) how the actual measurement of an etch shift (circular-shaped points in FIG. 4(a)) varies depending on an inter-pattern space 302. The horizontal axis shows the width (nm) of the inter-pattern space 302 and the vertical axis shows the etch shift (nm).

FIG. 4(b) shows a result obtained by fitting the values of the etch shift in the etching proximity effect correction model as shown in FIG. 4(a) to the actual measurements of the etch shift as shown in FIG. 4(a). The horizontal axis shows the width (nm) of the inter-pattern space 302 and the vertical axis shows the residual error (nm) generated in the fitting (model fitting residual error).

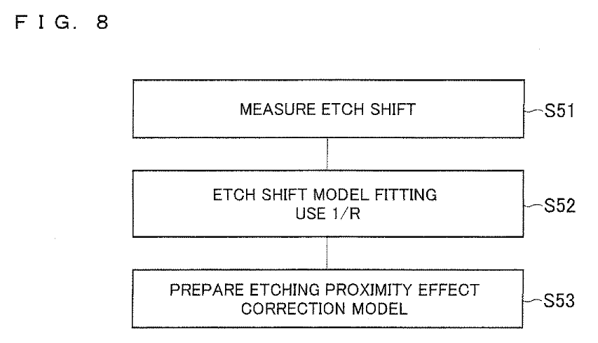

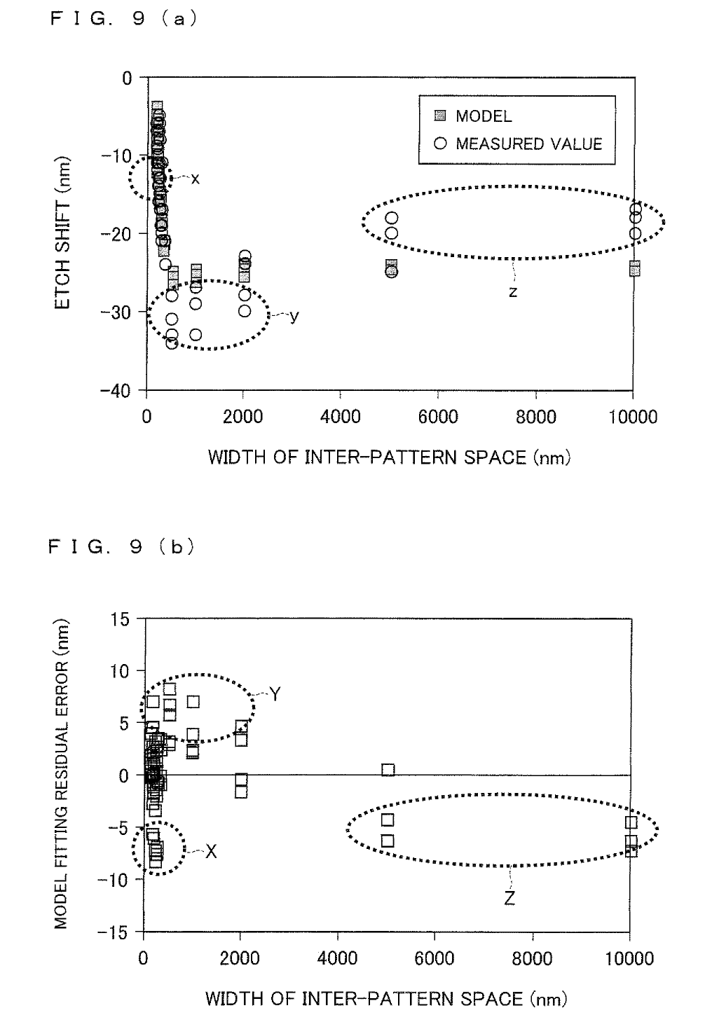

As described above, according to the conventional etching proximity effect correction model prepared based on the steps shown in FIG. 8, there remain residual errors more than 5 nm in the respective space regions, as shown in FIG. 9(b). In contrast, according to an etching proximity effect correction model described in accordance with the present embodiment, which is prepared based on the steps shown in FIG. 1, there occurs no model fitting residual error more than 5 nm in any space region, as FIG. 4(b) shows.

Thus, in the etching proximity effect correction model prepared based on the steps shown in FIG. 1, a good conformity to the actual measurements is obtained. Therefore, it is possible to prepare an etching proximity effect correction model having a high accuracy.

Note that the function R⁻ⁿ has good reproducibility of a pattern dependency, including a dependency on the shape of the lower part of the resist, that occurs during the etching of the organic antireflective film 204 provided under the photo resist. The logarithmic function Log(R) has good reproducibility of a pattern dependency that occurs during the etching of the polycrystalline silicon film 203 so that the gate wiring pattern 207 is formed. Therefore, since the etching proximity effect correction model includes the equation in which the function R⁻ⁿ and the logarithmic function Log(R) are linearly combined, it is possible to realize an etching proximity effect correction model having high accuracy.

Thus, the reason why a conventional etching proximity effect correction model has a low accuracy seems to be because the conventional etching proximity effect has not dealt with the following facts. Namely, (i) in a space region where the inter-pattern space has a wider width, a sidewall protection effect caused by generation of a by-product during etching and by entering of the by-product into sidewalls of the pattern depends on the Log function of the inter-pattern space R and (ii) in a space region where the inter-pattern space has a narrower width, on the other hand, the etch shift depends on the function R⁻² of the inter-pattern space R because the mask pattern trails. The dependencies in the (i) and (ii) causes a deterioration in accuracy.

Furthermore, particularly, the function R⁻¹ has good reproducibility of a pattern dependency that occurs during the etching of the organic antireflective film 204. On the other hand, the function R⁻², particularly, has good reproducibility of a dependency on the shape of the lower part of the resist pattern 205 that occurs during the pattern shifts caused by the etching. When a fitting was actually carried out by substituting n=3, 2, 1, and −1 in the function R⁻ⁿ, so that an etching proximity effect correction model was prepared, it was confirmed that n=2 and n=1 are the parameters which greatly affect an improvement in accuracy of an etching proximity effect correction model. Thus, the function R⁻ⁿ is preferably to be set within a range of 1≦n≦2.

Moreover, in a case that an etching proximity effect correction model is prepared, based on an etch shift calculated with the use of an etching proximity effect evaluation pattern in which a repeat pattern having a predetermined pattern pitch 303 as shown in FIG. 3 is provided, an etch shift can be calculated easily while parameters of a pattern size and an inter-pattern space size are not complex and so can be easily extracted. Therefore, it is possible to easily prepare a model so that the etch shift is dealt with by using the pattern size and the inter-pattern space size as parameters.

Now, the following description deals with the pattern size and the inter-pattern space size which are used as the parameters by the etching proximity effect correction model.

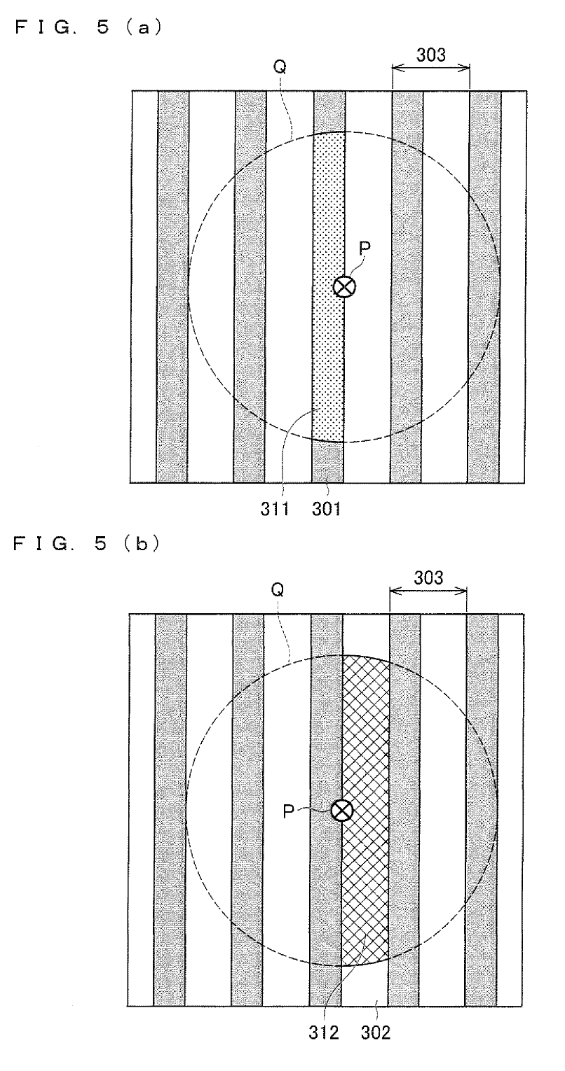

In a case that a repeat pattern as shown in FIG. 3 is set, a part 311 (see FIG. 5(a)) of a pattern 301, located within a range Q which is set for a point P that is subjected to a pattern correction, is supposed to be an object from which a value of the pattern size is extracted. Similarly, a part 312 (see FIG. 5(b)) of the inter-pattern space 302, located within a range Q which is set for a point P that is subjected to a pattern correction, is supposed to be an object from which a value of the inter-pattern space size is extracted.

As to a case of a one-dimensional (crosswise direction in figure) pattern such as the repeat patterns shown in FIGS. 5(a) and 5(b), a pattern size equals to a width of a part 311 and an inter-pattern space size equals to a width of a part 312. As such, when shifting one point P to be subjected to the pattern correction to another, it is possible, for each shifting of the point P, to extract values of the pattern size and the pattern space size.

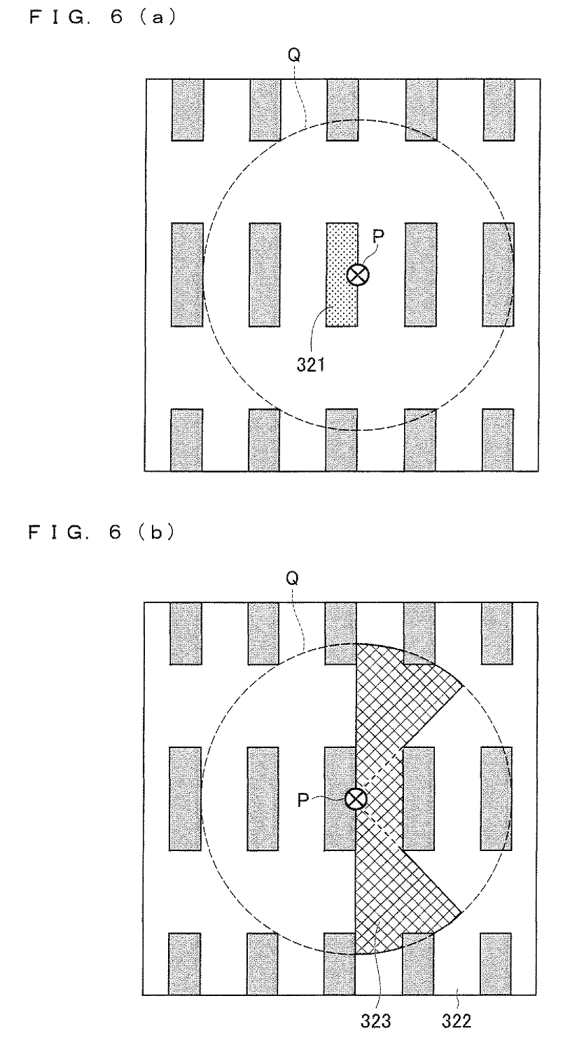

As to a case of, for example, a two-dimensional (lengthwise and crosswise directions) pattern, an area within a range Q that is set for a point P that is subjected to a pattern correction, which area is viewed on a line, is supposed to be an object from which a value of a pattern size and a value of an inter-pattern space size are extracted. That is to say, as shown in FIG. 6(a), the pattern size equals to an area (square measure) of a pattern 321 while, as shown in FIG. 6(b), the inter-patter space size equals to an area of a part 323 of an inter-pattern space 322, located within a range Q which is set for a point P that is subjected to a pattern correction.

[A Method of Manufacturing Semiconductor Device]

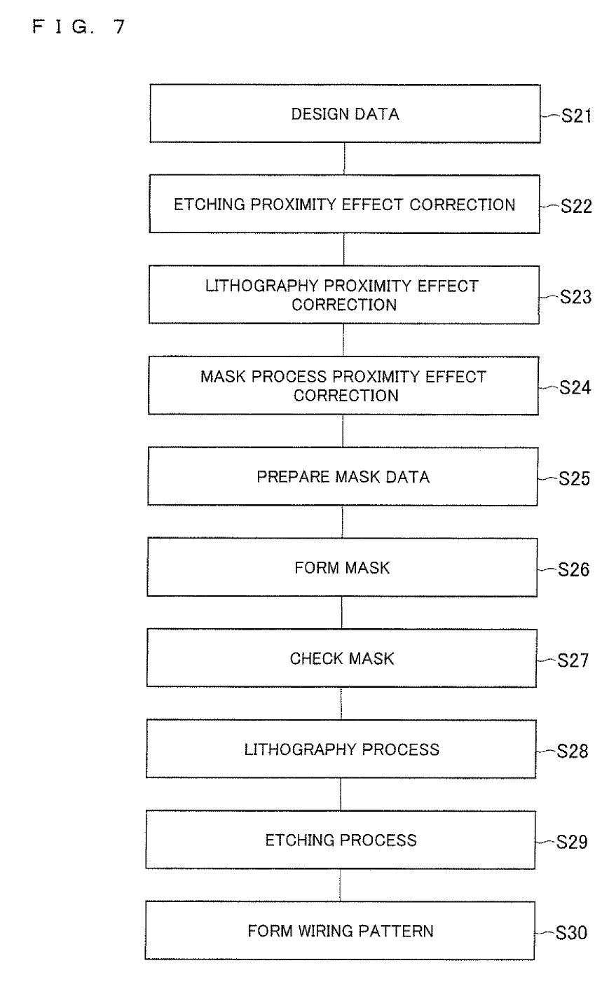

With reference to FIG. 7, the following description deals with a method of manufacturing a semiconductor device, in which method a wiring pattern of a gate is formed on a substrate based on a micro-fabrication process, with the use of a mask having a mask pattern which is corrected by use of an etching proximity effect correction model prepared based on the process described above.

FIG. 7 is a flow chart for showing a manufacturing flow in a method of manufacturing a semiconductor device.

First, design data for manufacturing a semiconductor device, that is to say, mask data for forming a gate, is prepared (step S21). Alternatively, it will be possible to use mask data which is prepared in advance.

Subsequently, an etching proximity effect correction is carried out with respect to the mask data, that is to say, with respect to a mask pattern, by correcting a pattern size and an inter-pattern space size, by use of an etching proximity effect correction model that is prepared based on the above process (step S22). That is to say, the mask data that has been subjected to the etching proximity effect correction is prepared by correcting the mask pattern with the use of the etching proximity effect correction model. The correction of the mask pattern is carried out as follows. Specifically, the correction is carried out with respect to a two-dimensional design pattern, by use of the etching proximity effect correction model defined by the two-dimensional pattern size and inter-pattern space size respectively shown in FIGS. 6(a) and 6(b). This makes it possible to realize a correction process with high accuracy.

Then, a lithography proximity effect correction is carried out with respect to the mask data that has been subjected to the etching proximity effect correction, by correcting, with the use of a lithography proximity correction model, the pattern size and the inter-pattern space size of the mask pattern (step S23). By this, the mask data that has subjected to the lithography proximity effect correction is prepared. Note that a conventional and ordinal method can be suitably used, as to the method of carrying out, with the use of the lithography proximity effect correction model, the lithography proximity effect correction.

Then, a mask process proximity effect correction is carried out with respect to the mask data subject to the lithography proximity effect correction, by correcting, with the use of a mask process proximity effect correction model, the pattern size and the inter-pattern space size of the mask pattern (step S24). By this, the mask data that has been subjected to the mask process proximity effect correction is prepared (step S25). Note that a conventional and ordinal method can be suitably used, as to the method of carrying out, with the mask process proximity effect correction model, the mask process proximity effect correction.

Then, a process proximity effect correction mask is prepared, with the use of an ordinal method of forming a photo mask, based on the mask data that has been subjected sequentially to the etching proximity effect correction, the lithography proximity effect correction, and the mask process proximity effect correction (step S26). Thereafter, a pattern defect of the process proximity effect correction mask is checked with the use of an ordinal defect check device (step S27).

A process proximity effect correction mask which is checked and confirmed that no defect is found during the checking is regarded as a process proximity effect correction mask having a mask pattern corrected based on mask data that has been subjected to an etching proximity effect correction with the use of a highly accurate etching proximity effect correction model.

Then, a lithography process is carried out (step S28). Specifically, a resist pattern is formed on the base configuration of the semiconductor device that is to be subjected to formation of a gate wiring pattern, with the use of a process proximity effect correction mask and the lithography conditions used during preparation of the etching proximity effect correction model.

Then, an etching process is carried out based on the resist pattern thus prepared (step S29). Specifically, the etching process is carried out by using the resist pattern as a mask and under the etching condition used in the preparation of the etching proximity effect correction model. By this, the gate wiring pattern is formed with respect to the base configuration (step S30).

As described above, the gate wiring pattern is formed based on the mask data that has been subjected sequentially to the etching proximity effect correction, the lithography proximity effect correction, and the mask process proximity effect correction. As such, the gate wiring pattern can be formed accurately with dimensions as designed. Beside, it is also possible to suppress variations in gate line widths so as to downsize gate dimensions. Therefore, it becomes possible to realize an improvement in speed and in integration of transistors.

Though the above description deals with a case where a mask pattern of a gate is corrected, the present invention is not particularly limited to this. For example, the present invention can be also used for correcting mask patterns of various types of wiring of a semiconductor device.

The above description deals with a case where a correction of a mask pattern is carried out so as to deal with the etching proximity effect with the use of an etching proximity effect correction model in which a pattern size and an inter-pattern space size are set as parameters. It is possible to calculate etch shifts, based on an etching proximity effect correction model, with respect to various pattern sizes and inter-pattern space sizes. As such, it is possible to carry out a correction of a mask pattern so as to deal with the etching proximity effect with the use of a correction rule in which a correction amount is defined based on combinations of pattern sizes and inter-pattern space sizes. The following description deals with an example of such a correction rule.

[Correction Rule]

With the use of an etching proximity effect correction model prepared based on the process shown in FIG. 1, correction amounts are calculated for a pattern width and an inter-pattern space width so as to have a regular interval (e.g., 1 nm). Then, combinations (a correction rule table) of (i) the correction amounts thus calculated and (ii) the pattern width and the inter-pattern space width are prepared. This makes it possible to define the correction rule.

A correction process using a correction rule is supposed to be limit to a one-dimensional (crosswise direction) correction of the crosswise space as shown in FIGS. 5(a) and 5(b). Specifically, in a layout of the pattern to be corrected, an edge of a pattern is subdivided by a regular length (e.g., 50 nm) into edge segments. Then, a pattern width and an inter-pattern space width of each of the edge segments are measured. After this, with reference to a correction rule table, a correction amount is extracted based on the pattern width and inter-pattern space width thus measured. A pattern correction process is carried out by shifting, by the correction amount, the edge of the pattern in the edge segments.

A correction process directly using an etching proximity effect correction model is carried out with respect to a two-dimensional design pattern as shown in FIGS. 6(a) and 6(b), whereas a correction process using a correction rule defined by the data calculated with the use of an etching proximity effect correction model is carried out with respect to a one-dimensional (crosswise direction) design pattern, i.e., space in the crosswise direction, as shown in FIGS. 5(a) and 5(b).

Therefore, when carrying out a correction process, a correction process using a correction rule merely measures a pattern size and an inter-pattern space size of each edge segment in a one-dimension manner (in a crosswise direction). Consequently, it is possible to shorten a time period required for the correction process. Note however that correction accuracy gets lowered in some degree since only the pattern size and the inter-pattern space size in a one-dimension manner (in a crosswise direction) are measured.

The present invention is not limited to the description of the embodiments above, but may be altered by a skilled person within the scope of the claims. An embodiment based on a proper combination of technical means disclosed in different embodiments is encompassed in the technical scope of the present invention.

The present invention is not only suitably applicable to a field related to a method of correcting a mask pattern such as a photo mask, but also applicable to a field related to a semiconductor device having a wiring pattern formed with the use of a mask. The present invention is further suitably applicable to a field related to the manufacture of a semiconductor device such as a field related to a lithography process or an etching process.

As described above, a method for correcting a mask pattern in accordance with the present invention is a method in which, before carrying out the micro-fabrication process, the mask pattern is corrected so that the etching proximity effect is dealt with, by use of the correction model in which the pattern size and the inter-pattern space size are set as the parameters.

Since the pattern size and the inter-pattern space size are set in the correction model, as the parameter, the correction model is prepared accurately. Thus, it is possible to obtain an effect that the mask pattern can be corrected with high accuracy so that a wiring pattern having desired dimensions is formed on the substrate, thereby dealing with the etching proximity effect.

Besides, the method for correcting the mask pattern in accordance with the present invention is preferably arranged such that the correction model includes at least the equation in which the function R⁻ⁿ (n: a positive real number) and the logarithmic function Log(R) are linearly combined, where the parameter of the inter-pattern space size is R.

With this arrangement, the function R⁻ⁿ has good reproducibility of the pattern dependency, including the dependency on the shape of the lower part of the resist for example, that occurs during the etching of the organic antireflective film provided under the photo resist while the logarithmic function Log(R) has good reproducibility of the pattern dependency that occurs during the etching of the material of the wiring pattern e.g., polycrystalline silicon. This allows a further improvement in accuracy of the correction model.

Besides, particularly, the function R⁻¹ has good reproducibility of the pattern dependency that occurs during the etching of the organic antireflective film. On the other hand, the function R⁻², particularly, has good reproducibility of the dependency on the shape of the lower part of the resist pattern that occurs during the pattern shifts caused by the etching. Therefore, the method for correcting the mask pattern in accordance with the present invention is preferably arranged such that the function R⁻ⁿ is set so that n falls within a range of 1≦n≦2.

Furthermore, the method for correcting the mask pattern in accordance with the present invention is preferably arranged such that the correction model is prepared based on data obtained from the substrate having the wiring pattern formed by use of the evaluation pattern in which the repeat pattern having a regular pattern pitch is set.

With this arrangement, it is possible to easily collect, from the substrate having the wiring pattern, the data of the pattern shifts caused by the etching. In addition, since the pattern size and the inter-pattern space size are not complex to be extracted, it is possible to easily prepare the model on the data of the pattern shifts by using, as the parameter, the pattern size and the inter-pattern space size.

Also, the method for correcting the mask pattern in accordance with the present invention is preferably arranged such that the pattern size and the inter-pattern space size are one-dimensional sizes; the correction rule is prepared by use of the correction model, the correction rule defining a correction amount calculated from a combination of the pattern size and the inter-pattern space size; and the mask pattern is corrected based on the correction rule so that the etching proximity effect is dealt with.

With this arrangement in which only the pattern size and the inter-pattern space size in one-dimension (e.g., crosswise direction) require to be detected during the correction process, it is possible to shorten the time period required for the correction process.

Moreover, the photo mask in accordance with the present invention has the mask pattern that has been subjected to the correction so that the etching proximity effect is dealt with, by use of the correction model in which the pattern size and the inter-pattern space size are set as the parameters.

Therefore, it is possible to obtain the effect that the photo mask having the mask pattern that is corrected with high accuracy so that the wiring pattern having desired dimensions is formed on the substrate, thereby dealing with the etching proximity effect.

In addition, the method for manufacturing the semiconductor device in accordance with the present invention includes the steps of: correcting the mask pattern of the mask so that the etching proximity effect is dealt with, by use of the correction model in which the pattern size and the inter-pattern space size are set as the parameters; and forming the wiring pattern on the substrate in the micro-fabrication process, by use of the mask having the mask pattern that has been subjected to the correcting. Thus, it is possible to form, with high accuracy, the wiring pattern having the desired dimensions on the substrate.

Also, the semiconductor device in accordance with the present invention has the wiring pattern formed on the substrate based on the micro-fabrication process using the mask having the mask pattern that has been subjected to the correction, by use of the correction model in which the pattern size and the inter-pattern space size are set as the parameters, so that the etching proximity effect is dealt with.

By this, the mask pattern of the mask is corrected with high accuracy so that the etching proximity effect is dealt with. Thus, it is possible to realize the semiconductor device having the wiring pattern that has the desired dimensions and that is formed on the substrate with high accuracy.

As a result, the effects obtained with the present invention suppress a variance in the widths of the various types of wirings and advance the downsizing. Therefore, it is further possible to obtain an effect that quality and performance of a transistor radio and, ultimately, quality and performance of a semiconductor device, can be significantly enhanced.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A method of correcting a mask pattern of a mask such that a wiring pattern having desired dimensions is formed based on a micro-fabrication process using the mask, wherein:
before carrying out the micro-fabrication process, the mask pattern is corrected so that an etching proximity effect is dealt with, by use of a correction model in which a pattern size and an inter-pattern space size are set as parameters.

2. The method as set forth in claim 1, wherein the correction model includes at least an equation in which a function R⁻ⁿ (n: a positive real number) and a logarithmic function Log(R) are linearly combined, where the parameter of the inter-pattern space size is R.

3. The method as set forth in claim 2, wherein the function R⁻ⁿ is set so that n falls within a range of 1≦n≦2.

4. The method as set forth in claim 1, wherein the correction model is prepared based on data obtained from a substrate having a wiring pattern formed by use of an evaluation pattern in which a repeat pattern having a regular pattern pitch is set.

5. The method as set forth in claim 1, wherein:
the pattern size and the inter-pattern space size are one-dimensional sizes,
a correction rule is prepared by use of the correction model, the correction rule defining a correction amount calculated from a combination of the pattern size and the inter-pattern space size; and
the mask pattern is corrected based on the correction rule so that the etching proximity effect is dealt with.

6. A photo mask, comprising a mask pattern that has been subjected to a correction so that an etching proximity effect is dealt with, by use of a correction model in which a pattern size and an inter-pattern space size are set as parameters.

7. A method of manufacturing a semiconductor device in which a wiring pattern is formed on a substrate based on a micro-fabrication process using a mask, comprising the steps of:
correcting a mask pattern of the mask so that an etching proximity effect is dealt with, by use of a correction model in which a pattern size and an inter-pattern space size are set as parameters; and
forming the wiring pattern on the substrate in the micro-fabrication process, by use of the mask having the mask pattern that has been subjected to the correcting.

8. A semiconductor device, comprising a wiring pattern formed on a substrate based on a micro-fabrication process using a mask having a mask pattern that has been subjected to a correction so that an etching proximity effect is dealt with by, use of a correction model in which a pattern size and an inter-pattern space size are set as parameters.
